(19) United States
(12) Patent Application Publication
(10) Pub. No.: US 2017/0317223 A1
(43) Pub. Date: Nov. 2, 2017

(54) CERAMIC CARRIER BODY HAVING SOLAR CELLS

(71) Applicant: CeramTec GmbH, Plochingen (DE)

(72) Inventors: Thomas BETZ, Weiden (DE); Harald KRESS, Langenzenn (DE)

(21) Appl. No.: 15/502,953

(22) PCT Filed: Aug. 12, 2015
(86) PCT No.: PCT/EP2015/068545

§ 371 Date: Jul. 10, 2017

(30) Foreign Application Priority Data
Aug. 12, 2014 (DE) 10 2014 215 971.7

(51) Int. Cl. H01L 31/052; H01L 31/02

(52) U.S. Cl. CPC H01L 31/052; H01L 31/02008; H01L 31/0521

(57) ABSTRACT

The invention relates to a carrier body (1) for solar cells (2). According to the invention, in order to significantly improve the thermal resistivity of the connection between a solar cell (2) and the carrier body (1) or a cooling element, the carrier body (1) is made of a ceramic material having sintered metallization regions (3), at least one solar cell (2) is soldered or sintered onto the carrier body (1) and electrically connected to the metallization regions (3), and the carrier body (1) has ceramic cooling elements.

The invention relates to a carrier body for solar cells.

The efficiency of solar cells decreases with increasing temperature. This can be remedied by attaching an Al cooling element. The connection is established by contact pressure or heat conducting pastes. Such a connection between the solar cell and a metallic cooling element has high thermal resistivity. This type of cooling is not effective specifically for high-performance solar cells. The term solar cell means a photovoltaic cell.

The invention addresses the problem of improving a carrier body for solar cells in a manner which significantly reduces the thermal resistivity of the connection between the solar cell and the carrier body and/or a cooling element.

According to the invention, this problem is addressed in that the carrier body is made of a ceramic material with sintered metallization regions, at least one solar cell is soldered or sintered onto the carrier body and electrically connected to the metallization region, and the carrier body has ceramic cooling elements. As a result, the thermal resistivity is significantly improved, the solar cells are sufficiently cooled, the degree of efficiency is improved, and the service life is prolonged. Carrier bodies made of a ceramic material with sintered metallization regions quickly lead off heat which arises and distribute it into the carrier body. The cooling elements of the carrier body ultimately dissipate the heat into the surroundings.

In one embodiment, the carrier body can have a three-dimensional structure as cooling elements, producing the largest possible surface area—such as fins for air cooling—or the cooling elements are closed internal channels or chambers with supply ports for externally supplied cooling with gas or liquid. Advantageously, the internal passages and chambers have the greatest possible surface area. As such, the cooling can either be performed by a gas, in particular by air, or by liquids.

In a preferred embodiment, the carrier body is plate-shaped in design and thus has a top side, a bottom side, and lateral surfaces, wherein sintered metallization regions are arranged both on the top side and on the bottom side, and are electrically connected via sintered metallization regions on the lateral surfaces and on the corners. Alternatively, the metallization can be connected from the top side to the bottom side by one or more through-connections (vias). In this case, one or more solar cells are preferably soldered onto the metallizations on one of the top and bottom sides, wherein electrical or electronic control elements for the at least one solar cell are soldered onto the metallizations of the other side. This separation of the solar cells from the electrical or electronic controls has the advantage that the electrical or electronic controls are decoupled from the heat of the solar cells—that is, they are not subjected to increased heat stress.

The ceramic material is preferably Al₂O₃, MgO, SiO₂, mixed oxide ceramics, or nitride ceramics such as AlN, Si₃N₄.

A method according to the invention for the production of a carrier body according to one of the claims 1 to 5 is characterized in that the carrier body is produced with internal channels or chambers and forms a cooling unit and is printed with AgPt paste by means of a screen printing, pad printing, or stencil printing process, which is then burned in, then a solar cell is electroplated on its reverse side with Ag, and then the cooling unit and the solar cell are connected by, for example, a solder sheet interposed therebetween.

Another method according to the invention for the production of a carrier body according to one of the claims 1 to 5 is characterized in that the carrier body is produced with internal channels or chambers and forms a cooling unit and is printed with AgPt paste by means of a screen printing, pad printing, or stencil printing process, which is then burned in, then a solar cell is degreased and a paste with ultra-fine silver particles is printed onto the cooling unit by means of a screen printing process, and then the solar cell is placed thereon and a solid metal composite is produced.

Solar cells are soldered or sintered onto the sintered metallization regions of the ceramic carrier body. The cooling elements connected to the carrier body can be simple ceramic substrates; they can have a three-dimensional structure (e.g., fins), or they can have closed channels or chambers (with supply connections) to the outside. The cooling itself can be performed by a gas or with a liquid.

Metallizations can be filled and cured paints, the conventional thick film metallizations such as tungsten, molybdenum, silver, silver-palladium, silver-platinum, etc., and/or AMB or DCB composite bodies.

The cooling elements can be made of the conventional ceramics, such as Al₂O₃, MgO, SiO₂, mixed oxide ceramics, or nitride ceramics such as AlN, Si₃N₄. The shaping into the required form can be performed directly by film casting, extrusion, dry pressing, injection molding, hot casting, die casting, additive or generative design (3D printing), or by mechanical processing of blankets made of ceramic materials or of non-sintered moldings (green bodies) which are sintered subsequently.

### EXAMPLE A

A cooling unit made of AlN is printed with AgPt by means of a screen printing process, which is then burned in. A solar cell is electroplated on the reverse side thereof with Ag. At about 265° C., the cooling unit and the solar cell are connected by a solder sheet interposed therebetween.

### EXAMPLE B

A cooling unit made of AlN is printed with AgPt by means of a screen printing process, which is burned in at about 860° C. A solar cell is degreased. Then, a paste with ultra-fine silver particles is printed onto the cooling unit by means of a screen printing process. The solar cell is placed thereon, and at about 400° C. with access to air a solid metallic composite is produced.

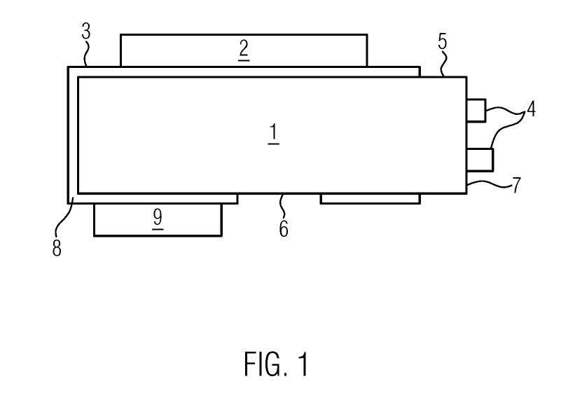

FIG. 1 shows an inventive embodiment of a carrier body 1 of a ceramic material. The carrier body 1 has a top side 5, a bottom side 6, and lateral surfaces 7. The metallization regions which are sintered to the carrier body 1, and which form a printed circuit board, are indicated by the reference number 3. In the embodiment shown here, these metallization regions 3 are arranged on the top side 5 as well as on the bottom side 6 and the lateral faces 7 and the corners 8. Solar cells 2 are arranged only on the top side 5. Their control elements 9 are situated on the bottom side 6. FIG. 1 is not to scale. Cooling channels, which are not shown here, are arranged in the carrier body 1, which is also simultaneously the cooling element in this case, and are connected to the supply connections 4. Cooling fluid which cools the carrier body is conveyed via these supply connections 4 into the carrier body 1. Solar cells 2 are soldered in this case onto the metallization regions 3 only on the top side 5.

1. A carrier body for solar panels, wherein the carrier body is made of a ceramic material with sintered metallization regions, at least one solar cell is soldered or sintered onto the carrier body and is electrically connected to the metallization regions, and the carrier body has ceramic cooling elements.

2. The carrier body according to claim 1, wherein the carrier body has a three-dimensional structure as cooling elements, such as fins, for air cooling, or closed internal channels or chambers with supply ports to the outside, for a gas or a cooling liquid.

3. The carrier body according to claim 1, wherein the carrier body is plate-shaped in design, has a top side, a bottom side, and lateral surfaces, and sintered metallization regions are arranged both on the top side and on the bottom side and are electrically connected via sintered metallization regions on the lateral surfaces and on the corners, or by through-connections (vias).

4. The carrier body according to claim 3, wherein one or more solar cells are soldered onto the metallization regions on either the top side or the bottom side, and electrical or electronic controls for the at least one solar cell are soldered onto the metallization regions of the other respective top side or bottom side.

5. The carrier body according to claim 1, wherein the ceramic material is Al₂O₃, MgO, SiO₂, mixed oxide ceramics, or nitride ceramics such as AlN, Si₃N₄.

6. A method for the production of a carrier body according to claim 1, wherein the carrier body is made with inner channels or chambers made of ceramic, and forms a cooling unit, and is printed with AgPt paste by means of a printing process (such as screen, pad or stencil printing), which is then burned in, and then a solar cell is electroplated on its reverse side with Ag, and the cooling unit and the solar cell are connected by a solder sheet interposed therebetween.

7. The method for the production of a carrier body according to claim 1, wherein the carrier body is produced with internal channels or chambers and forms a cooling unit, and is printed with AgPt paste by means of a printing process (screen, pad, or stencil printing), which is then burned in, and then a solar cell is degreased and a paste with ultra-fine silver particles is printed onto the cooling unit by means of a screen printing process, and then the solar cell is placed thereon and a solid metal composite is produced.
